(19) United States
(12) Patent Application Publication
(10) Pub. No.: US 2026/0255907 A1
(43) Pub. Date: Aug. 27, 2026

(54) SUBSTRATE PROCESSING APPARATUS AND METHOD

(71) Applicant: ZEUS CO., LTD., Hwaseong-si (KR)

(72) Inventors: Wi Seob KANG, Hwaseong-si (KR); Seung Tae KIM, Hwaseong-si (KR); Wu Shin CHA, Hwaseong-si (KR); Byeong Jun LEE, Hwaseong-si (KR); Jae Hwan SON, Hwaseong-si (KR); Keum Dong HEO, Hwaseong-si (KR); Gun Hyung KIM, Hwaseong-si (KR)

(73) Assignee: ZEUS CO., LTD., Hwaseong-si (KR)

(21) Appl. No.: 19/548,217

(22) Filed: Feb. 24, 2026

(30) Foreign Application Priority Data
Feb. 27, 2025 (KR) 10-2025-0026107

(51) Int. Cl. H10P 72/00; B08B 3/08; B08B 13/00

(52) U.S. Cl. CPC H10P 72/0404; B08B 3/08; B08B 13/00

(57) ABSTRACT

A substrate processing apparatus and a substrate processing method are disclosed, the disclosed substrate processing apparatus includes a substrate support part configured to support a substrate, a discharge part configured to discharge a chemical liquid onto the substrate, and a cup including a collection wall part surrounding the substrate support part such that the chemical liquid discharged from the substrate support part after being discharged onto the substrate is collected, a trench part in which the chemical liquid falling along the collection wall part is collected, and a drain port provided at one side of the trench part such that the chemical liquid is discharged from the trench part, wherein a bottom of the trench part includes a first bottom part and a second bottom part stepped from the first bottom part and recessed further downward than the first bottom part.

### CROSS-REFERENCE TO RELATED APPLICATIONS

This U.S. non-provisional patent application claims priority to and the benefits of Korean Patent Application No. 10-2025-0026107 under 35 U.S.C. § 119, filed in the Korean Intellectual Property Office on February 27, 2025, the entire contents of which are hereby incorporated by reference.

### BACKGROUND

### 1. Technical Field

The present invention relates to a substrate processing apparatus and method for processing a substrate using a chemical liquid, which are used in semiconductor manufacturing.

### 2. Description of the Related Art

Semiconductor manufacturing processes may include a thin-film deposition process, an etching process, and a cleaning process. Among these, the cleaning process is a process of discharging a chemical liquid onto a substrate to remove particles or foreign substances remaining on the substrate. However, due to waste chemical liquid that is drained after being discharged onto the substrate, environmental burdens are increased and operating costs are also increased.

The background art of the present invention is disclosed in Korean Patent Laid-Open Publication No. 10-2012-0018296 (published on March 2, 2012, entitled “Semiconductor Wafer Cleaning Method and Apparatus”).

### SUMMARY

The present invention is directed to providing a substrate processing apparatus and a substrate processing method that are capable of reducing consumption of a chemical liquid used in substrate processing by recycling the chemical liquid used in the substrate processing.

According to an aspect of the present invention, there is provided a substrate processing apparatus including a substrate support part configured to support a substrate, a discharge part configured to discharge a chemical liquid onto the substrate, and a cup including a collection wall part surrounding the substrate support part such that the chemical liquid discharged from the substrate support part after being discharged onto the substrate is collected, a trench part in which the chemical liquid falling along the collection wall part is collected, and a drain port provided at one side of the trench part such that the chemical liquid is discharged from the trench part, wherein a bottom of the trench part includes a first bottom part and a second bottom part stepped from the first bottom part and recessed further downward than the first bottom part.

A vertical cross-sectional shape of the second bottom part may be a curved shape that is concavely recessed.

A vertical cross-sectional shape of the first bottom part may be an inclined linear shape in which a height increases in a width direction of the trench part away from the second bottom part.

The first bottom part may be provided as a pair of first bottom parts with the second bottom part interposed therebetween in a width direction of the trench part.

In a width direction of the trench part, a width occupied by the second bottom part may be greater than a width occupied by the first bottom part.

The trench part may extend along a closed-loop path surrounding the substrate support part, and a height of the bottom of the trench part may be lowest at a point at which the drain port is located and increases away from the point at which the drain port is located.

According to an aspect of the present invention, there is provided a substrate processing apparatus including a substrate support part configured to support a substrate, a discharge part configured to discharge a chemical liquid onto the substrate, and a cup including a collection wall part surrounding the substrate support part such that the chemical liquid discharged from the substrate support part after being discharged onto the substrate is collected, a trench part extending along a closed-loop path surrounding the substrate support part and configured to collect the chemical liquid falling along the collection wall part, and a drain port provided at one side of the trench part such that the chemical liquid is discharged from the trench part, wherein a height of a bottom of the trench part is lowest at a point at which the drain port is located and increases away from the point at which the drain port is located.

The chemical liquid may include a first chemical liquid and a second chemical liquid different from the first chemical liquid, and the cup may include a first cup that collects at least one of the first chemical liquid and the second chemical liquid, and a second cup configured to collect the second chemical liquid while being configured not to collect the first chemical liquid.

The substrate processing apparatus may further include a drain flow path configured to guide the second chemical liquid discharged from the second cup to an outside of the substrate processing apparatus, and a chemical liquid recovery part configured to recover the second chemical liquid discharged from the second cup.

The chemical liquid recovery part may include a recycling chemical liquid tank in which the second chemical liquid discharged from the second cup is accommodated, a chemical liquid recovery flow path branched from the drain flow path and configured to guide the second chemical liquid flowing along the drain flow path to the recycling chemical liquid tank, and a flow path switching part configured to selectively switch a flow direction of the second chemical liquid such that the second chemical liquid discharged from the second cup and entering the drain flow path is directed toward one of the recycling chemical liquid tank and the outside of the substrate processing apparatus.

The flow path switching part may be controlled to direct the second chemical liquid collected in the second cup toward the outside of the substrate processing apparatus before a concentration of the second chemical liquid collected in the second cup has become equal to a concentration of the second chemical liquid supplied to the discharge part, and to direct the second chemical liquid collected in the second cup toward the recycling chemical liquid tank after the concentration of the second chemical liquid collected in the second cup has become equal to the concentration of the second chemical liquid supplied to the discharge part.

The substrate processing apparatus may further include a first chemical liquid tank configured to accommodate the first chemical liquid supplied to the discharge part and a second chemical liquid tank configured to accommodate the second chemical liquid supplied to the discharge part, wherein the chemical liquid recovery part may include a chemical liquid recovery flow path branched from the drain flow path and configured to guide the chemical liquid flowing along the drain flow path to the second chemical liquid tank, and a flow path switching part configured to selectively switch a flow direction of the second chemical liquid such that the second chemical liquid discharged from the second cup and entering the drain flow path is directed toward one of the second chemical liquid tank and the outside of the substrate processing apparatus.

The flow path switching part may be controlled to direct the second chemical liquid collected in the second cup toward the outside of the substrate processing apparatus before a concentration of the second chemical liquid collected in the second cup has become equal to a concentration of the second chemical liquid in the second chemical liquid tank, and to direct the second chemical liquid collected in the second cup toward the second chemical liquid tank after the concentration of the second chemical liquid collected in the second cup has become equal to the concentration of the second chemical liquid in the second chemical liquid tank.

According to an aspect of the present invention, there is provided a substrate processing method including a first-cup first-chemical-liquid discharge operation of discharging a first chemical liquid at a first cup position, at which a level of an upper portion of a first cup corresponds to a level of a substrate support part, onto a substrate supported by the substrate support part, a first-cup second-chemical-liquid discharge operation of stopping the discharging of the first chemical liquid and discharging a second chemical liquid different from the first chemical liquid onto the substrate while maintaining the first cup position, a cup shifting operation of moving a second cup to a second cup position at which a level of an upper portion of the second cup corresponds to the level of the substrate support part, and a second-cup second-chemical-liquid discharge operation of discharging the second chemical liquid at the second cup position onto the substrate.

The substrate processing method may further include a second chemical liquid recovery operation of recovering the second chemical liquid after a concentration of the second chemical liquid that is positioned at the second cup position, discharged onto the substrate, and collected in the second cup has become equal to a concentration of the second chemical liquid discharged to the second cup.

At an initial time point of the second-cup second-chemical-liquid discharge operation, the concentration of the second chemical liquid collected in the second cup may be different from the concentration of the second chemical liquid discharged to the second cup.

The second chemical liquid recovery operation may be initiated after a preset time has elapsed from an initial time point of the second-cup second-chemical-liquid discharge operation.

The preset time may be a time required for a concentration of the second chemical liquid collected in the second cup to have become equal to a concentration of the second chemical liquid accommodated in the second chemical liquid tank.

The second cup may include a collection wall part surrounding the substrate support part such that the second chemical liquid discharged from the substrate support part after being discharged onto the substrate is collected, a trench part configured to collect the second chemical liquid falling along the collection wall part, and a drain port provided at one side of the trench part such that the second chemical liquid is discharged from the trench part, and a bottom of the trench part may include a first bottom part and a second bottom part stepped from the first bottom part and recessed further downward than the first bottom part.

The second cup may include a collection wall part surrounding the substrate support part such that the second chemical liquid discharged from the substrate support part after being discharged onto the substrate is collected, a trench part extending along a closed-loop path surrounding the substrate support part and configured to collect the second chemical liquid falling along the collection wall part, and a drain port provided at one side of the trench part such that the second chemical liquid is discharged from the trench part, and a height of a bottom of the trench part may be lowest at a point at which the drain port is located and increase away from the point at which the drain port is located.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a configuration diagram of a substrate processing apparatus according to a first embodiment of the present invention;

FIG. 2 is a configuration diagram of a process chamber of FIG. 1;

FIG. 3 is a configuration diagram illustrating a state in which a first cup and a second cup of FIG. 2 are raised;

FIG. 4 is a cross-sectional view illustrating the second cup separated from FIGS. 2 and 3;

FIG. 5 is an enlarged view of portion A of FIG. 4;

FIG. 6 is a cross-sectional view along line S1-S1 of FIG. 4;

FIG. 7 is a block diagram illustrating an example of a substrate processing method according to one embodiment of the present invention; and

FIG. 8 is a configuration diagram of a substrate processing apparatus according to a second embodiment of the present invention.

### DETAILED DESCRIPTION

Hereinafter, a substrate processing apparatus according to embodiments of the present invention will be described in detail with reference to the accompanying drawings. Terms used in the present specification are terms used to appropriately describe preferred embodiments of the present invention, and may vary depending on the intention of a user or an operator, or practices and conventions in a field to which the present invention pertains. Therefore, definitions of these terms should be determined based on the content throughout the present specification.

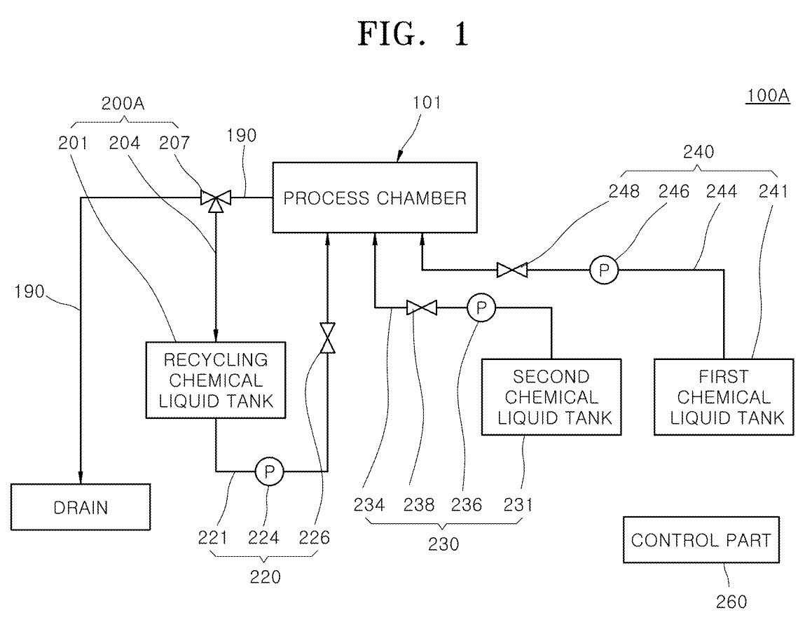

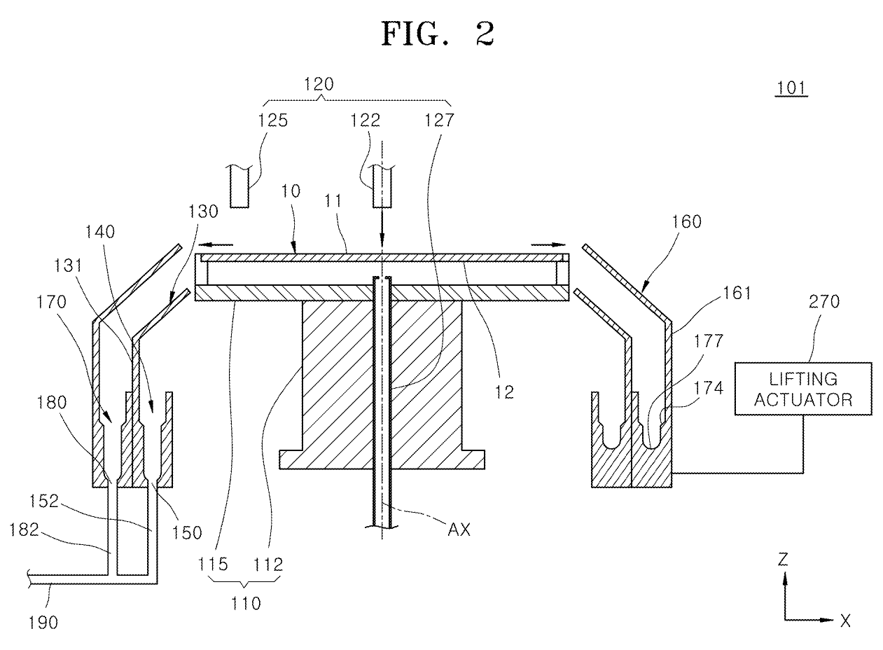

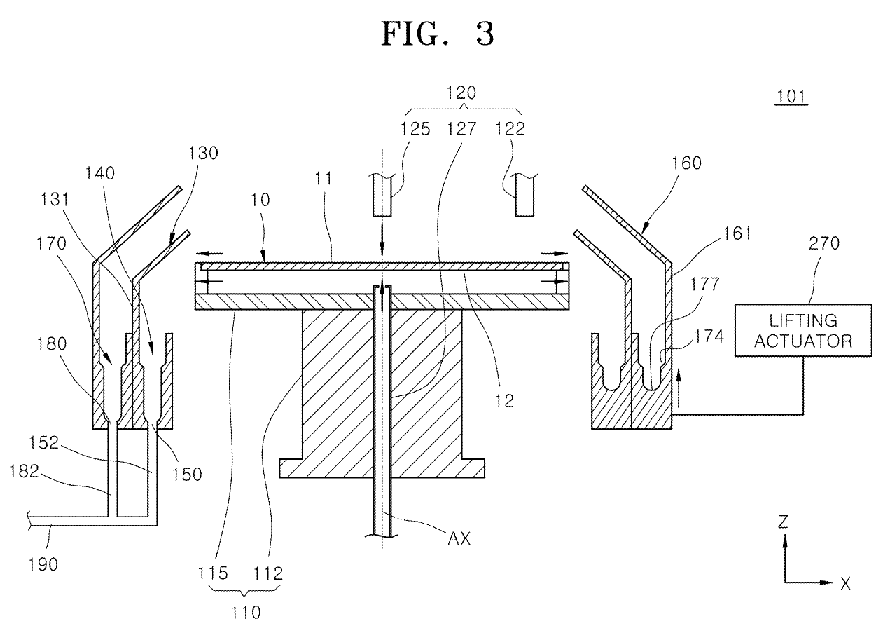

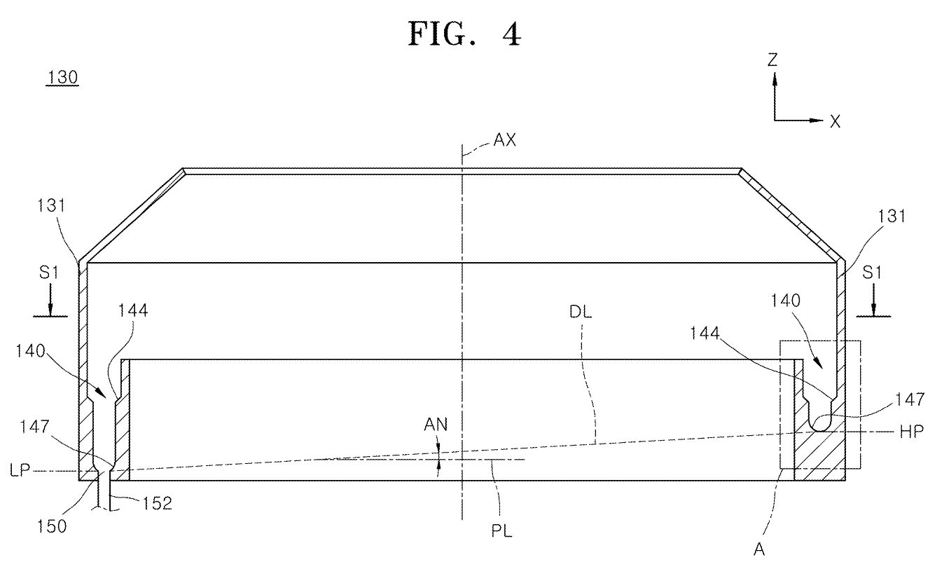

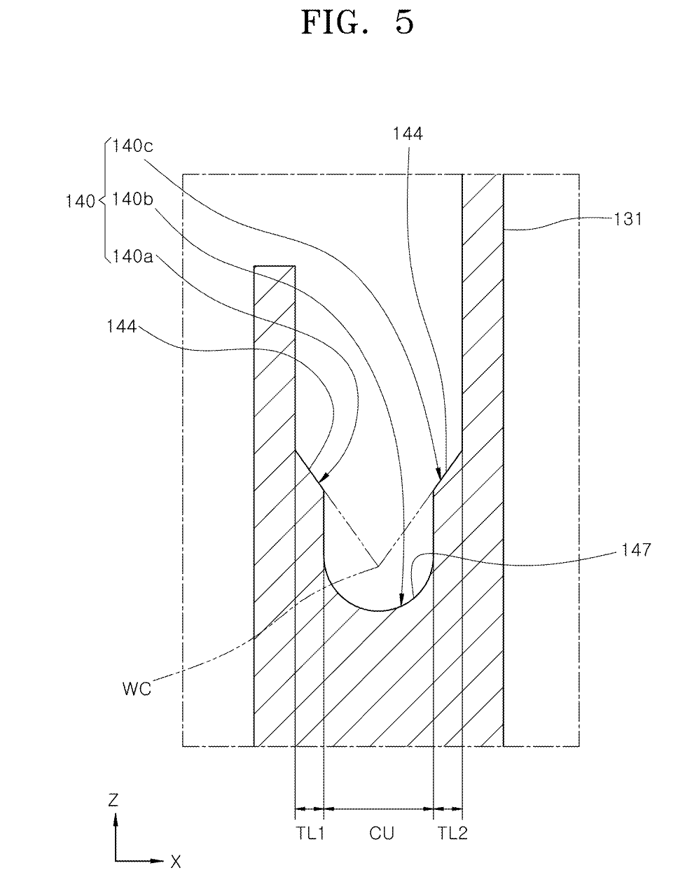

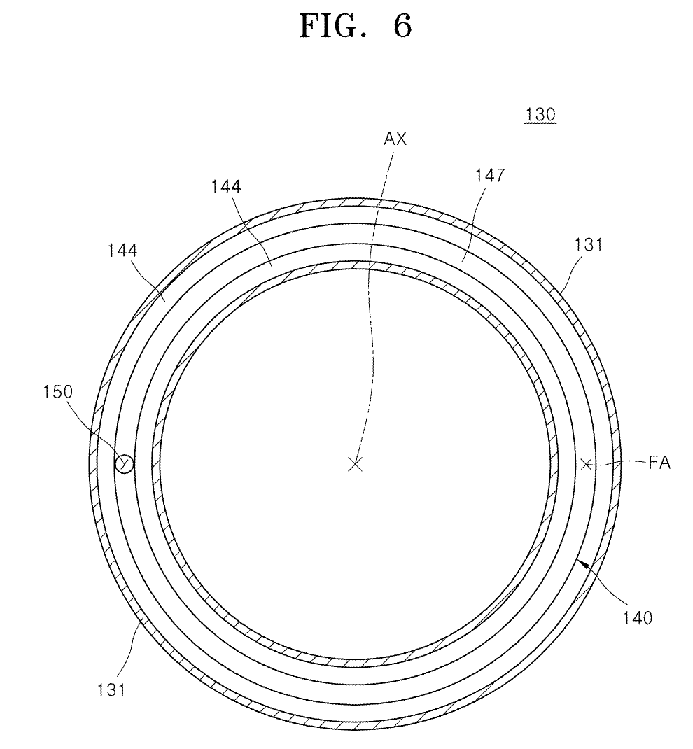

FIG. 1 is a configuration diagram of a substrate processing apparatus according to a first embodiment of the present invention, FIG. 2 is a configuration diagram of a process chamber of FIG. 1, FIG. 3 is a configuration diagram illustrating a state in which a first cup and a second cup of FIG. 2 are raised, FIG. 4 is a cross-sectional view illustrating the second cup separated from FIGS. 2 and 3, FIG. 5 is an enlarged view of portion A of FIG. 4, and FIG. 6 is a cross-sectional view along line S1-S1 of FIG. 4.

Referring to FIGS. 1 to 6, a substrate processing apparatus 100A according to the first embodiment of the present invention may be, for example, an apparatus for cleaning a substrate 10 by discharging a chemical liquid onto an upper surface 11 and a lower surface 12 of the substrate 10. The substrate 10 may be, for example, a disk-shaped semiconductor wafer.

The substrate processing apparatus 100A includes a process chamber 101. The process chamber 101 includes a substrate support part 110, a discharge part 120, and a second cup 130. Substrate processing is performed in the process chamber 101. The substrate processing apparatus 100A may further include a first chemical liquid supply part 240, a second chemical liquid supply part 230, and a chemical liquid recovery part 200A.

The substrate support part 110 supports the substrate 10. The substrate support part 110 may include a table 115 supporting the substrate 10, and a spindle 112 configured to rotate the table 115 at high speed about an axis AX in a vertical direction.

The discharge part 120 discharges a chemical liquid onto the substrate 10. The discharge part 120 may include a first chemical liquid nozzle 122 configured to discharge a first chemical liquid onto a surface of the substrate 10, for example, the upper surface 11. The discharge part 120 may include a second chemical liquid nozzle 125 configured to discharge, onto the upper surface 11 of the substrate 10, a second chemical liquid different from the first chemical liquid, and a third chemical liquid nozzle 127 configured to discharge the second chemical liquid onto the lower surface 12 of the substrate 10.

The second chemical liquid nozzle 125 may move along the axis AX so that the second chemical liquid is discharged onto a central portion of the substrate 10 when discharging the second chemical liquid and may move to an outer peripheral portion of the substrate 10 when not discharging the second chemical liquid. The first chemical liquid nozzle 122 may move along the axis AX so that the first chemical liquid is discharged onto the central portion of the substrate 10 when discharging the first chemical liquid and may move to the outer peripheral portion of the substrate 10 when not discharging the first chemical liquid.

In the embodiment illustrated in FIGS. 2 and 3, the first chemical liquid nozzle 122 is illustrated as discharging the first chemical liquid only onto the upper surface 11 of the substrate 10. However, in another embodiment of the present invention, the discharge part 120 may further include a first chemical liquid nozzle configured to discharge the first chemical liquid onto the lower surface 12 of the substrate 10.

The second chemical liquid supply part 230 may supply the second chemical liquid to the discharge part 120. For example, the second chemical liquid supply part 230 may supply the second chemical liquid to the second chemical liquid nozzle 125 and the third chemical liquid nozzle 127.

The second chemical liquid supply part 230 may include a second chemical liquid tank 231, a second chemical liquid supply flow path 234, a pump 236, and a valve 238. The second chemical liquid tank 231 may accommodate the second chemical liquid. The second chemical liquid may be, for example, any one of hydrogen fluoride (HF), sulfate peroxide (SP), sulfuric acid peroxide mixture (SPM), fluoric acid peroxide mixture (FPM), standard clean 1 (SC-1), and standard clean 2 (SC-2), or a combination thereof.

The second chemical liquid supply flow path 234 guides movement of the second chemical liquid from the second chemical liquid tank 231 to the discharge part 120. The second chemical liquid supply flow path 234 may include, for example, a pipe. The pump 236 may pump the second chemical liquid discharged from the second chemical liquid tank 231 toward the discharge part 120. The valve 238 opens and closes the second chemical liquid supply flow path 234 such that the second chemical liquid is selectively supplied to the discharge part 120.

Although not illustrated in FIG. 1, the second chemical liquid supply part 230 may further include a filter. The filter may filter impurities from the second chemical liquid supplied from the second chemical liquid tank 231 to the discharge part 120.

The first chemical liquid supply part 240 supplies the first chemical liquid to the discharge part 120. The first chemical liquid supply part 240 may include a first chemical liquid tank 241, a first chemical liquid supply flow path 244, a pump 246, and a valve 248. The first chemical liquid tank 241 may accommodate the first chemical liquid. For example, the first chemical liquid may be deionized water (DIW).

The first chemical liquid supply flow path 244 guides movement of the first chemical liquid from the first chemical liquid tank 241 to the discharge part 120. For example, the first chemical liquid may be supplied to the first chemical liquid nozzle 122. The first chemical liquid supply flow path 244 may include, for example, a pipe. The pump 246 may pump the first chemical liquid discharged from the first chemical liquid tank 241 toward the discharge part 120. The valve 248 opens and closes the first chemical liquid supply flow path 244 such that the first chemical liquid is selectively supplied to the discharge part 120.

Although not illustrated in FIG. 1, the first chemical liquid supply part 240 may further include a filter. The filter may filter impurities from the first chemical liquid supplied from the first chemical liquid tank 241 to the discharge part 120.

For example, the second chemical liquid discharged from the second chemical liquid nozzle 125 onto the upper surface 11 of the substrate 10 and the second chemical liquid discharged from the third chemical liquid nozzle 127 onto the lower surface 12 of the substrate 10 may be discharged from an outer peripheral portion of the table 115 in a radial direction by centrifugal force due to rotation of the table 115.

The second cup 130 collects a chemical liquid discharged from the substrate support part 110 after being discharged onto the substrate 10 as described above. The chemical liquid collected in the second cup 130 may be the second chemical liquid. The first chemical liquid may not be collected in the second cup 130.

The second cup 130 includes a collection wall part 131, a trench part 140, and a drain port 150. The collection wall part 131 surrounds the substrate support part 110. For example, the collection wall part 131 may surround the table 115 and may be erected in an up-down direction. An upper end portion of the collection wall part 131 may extend to be inclined toward the axis AX in an upward direction.

With reference to FIGS. 2 to 6, a horizontal direction may be a direction parallel to a plane including an X-axis and a Y-axis, and the vertical direction may be a direction parallel to a Z-axis. The up-down direction may be a direction intersecting the plane including the X-axis and the Y-axis. The up-down direction may be the same as the vertical direction.

Chemical liquid falling along the collection wall part 131 is collected in the trench part 140. As illustrated in FIG. 6, the trench part 140 may have an annular planar shape centered on the axis AX when viewed from above. In other words, the trench part 140 may extend along a circular path centered on the axis AX.

However, the present invention is not limited thereto, and in another embodiment, the trench part of the second cup may surround the substrate support part and may extend along a closed-loop path that is not circular.

The drain port 150 is provided at one side of the trench part 140. The chemical liquid discharged from the table 115 and collected in the trench part 140 is discharged to the outside of the second cup 130 through the drain port 150. The chemical liquid discharged through the drain port 150 may move to a drain flow path 190 through a drain tube 152.

The trench part 140 may include a first trench 140a and a second trench 140b. The first trench 140a may include a first bottom part 144, and the second trench 140b may include a second bottom part 147. The second trench 140b may be provided to be recessed downward from the first bottom part 144 of the first trench 140a. That is, the trench part 140 may be an integrated body in which the first trench 140a and the second trench 140b are connected. A width (TL1+CU+TL2) of the first trench 140a may be greater than a width CU of the second trench 140b.

A bottom of the trench part 140 includes the first bottom part 144 and the second bottom part 147. The second bottom part 147 is stepped from the first bottom part 144 and is recessed further downward than the first bottom part 144.

A vertical cross-sectional shape of the second bottom part 147 may be a curved shape that is concavely recessed. A vertical cross-sectional shape of the first bottom part 144 may be an inclined linear shape in which a height increases in a width direction of the trench part 140 away from the second bottom part 147.

In the width direction of the trench part 140, a pair of first bottom parts 144 may be provided with the second bottom part 147 interposed therebetween. Vertical cross-sectional shapes of the first bottom parts 144 may coincide with left-right symmetrical inclined lines that intersect at a central point WC of the trench part 140 in the width direction of the trench part 140.

For example, after forming a bottom having a V-shaped vertical cross-sectional shape by machining using a tool having a V-shaped cross section, the bottom may be further machined using a tool having a U-shaped cross section to form the second bottom part 147 having a U-shaped vertical cross-sectional shape.

Accordingly, the bottom of the trench part 140 including a pair of spaced first bottom parts 144 and one second bottom part 147 disposed between the pair of first bottom parts 144 may be formed.

In the width direction of the trench part 140, the width CU occupied by the second bottom part 147 may be greater than a width (TL1+TL2) occupied by the first bottom parts 144. Since the bottom of the trench part 140 further includes the second bottom part 147 in addition to the first bottom parts 144, the bottom of the trench part 140 is deeper than a trench part including only an inclined bottom having a V-shaped vertical cross-sectional shape, an amount of liquid that may be accommodated in the bottom increases, and a flow speed of the chemical liquid flowing in a vertical direction of the trench part 140 increases.

Accordingly, a larger amount of the chemical liquid may be quickly discharged to the outside of the second cup 130 through the drain port 150 from the trench part 140 of the second cup 130.

The bottom of the trench part 140 may have a lowest height LP at a point at which the drain port 150 is located, and the height of the bottom of the trench part 140 may increase away from the point at which the drain port 150 is located.

For example, a height HP of the bottom of the trench part 140 may be the highest at a point FA of the trench part 140 opposite to the point at which the drain port 150 is located with respect to the axis AX. A virtual straight line DL connecting the point of the bottom of the trench part 140 at which the drain port 150 is located and the point FA at which the height of the bottom of the trench part 140 is the highest may be inclined to form an acute angle AN with respect to a horizontal line PL.

As described above, since the height of the bottom of the trench part 140 decreases as the bottom becomes closer to the drain port 150 in a vertical direction of the bottom of the trench part 140, the chemical liquid collected in the trench part 140 may move toward the drain port 150 more quickly and may be discharged more quickly to the outside of the second cup 130 through the drain port 150.

The substrate processing apparatus 100A may further include, in the process chamber 101, a first cup 160 and a lifting actuator 270.

The first cup 160 collects a chemical liquid discharged from the substrate support part 110 after being discharged onto the substrate 10. At least one of the first chemical liquid and the second chemical liquid may be collected in the first cup 160.

For example, the first chemical liquid discharged from the first chemical liquid nozzle 122 onto the surface of the substrate 10 may be discharged from the outer peripheral portion of the table 115 in the radial direction by centrifugal force generated due to rotation of the table 115, and the first cup 160 may collect the first chemical liquid discharged from the substrate support part 110 after being discharged onto the substrate 10.

As another example, the second chemical liquid discharged from the second chemical liquid nozzle 125 and the third chemical liquid nozzle 127 onto the surface of the substrate 10 may be discharged from the outer peripheral portion of the table 115 in the radial direction by centrifugal force generated due to rotation of the table 115, and the first cup 160 may collect the second chemical liquid discharged from the substrate support part 110 after being discharged onto the substrate 10.

When the first chemical liquid is discharged onto the surface of the substrate 10 and then the second chemical liquid is discharged onto the surface of the substrate 10, the first chemical liquid remaining on the surface of the substrate 10 may be washed away and discharged from the substrate support part 110 together with the second chemical liquid into the first cup 160. As a result, a mixed chemical liquid of the first chemical liquid and the second chemical liquid may be collected in the first cup 160.

The first cup 160 includes a collection wall part 161, a trench part 170, and a drain port 180. The collection wall part 161 surrounds the substrate support part 110. For example, the collection wall part 161 may surround the table 115 and may be erected in the up-down direction. An upper end portion of the collection wall part 161 may extend to be inclined toward the axis AX in an upward direction.

A level of an upper portion of the first cup 160 may be different from a level of an upper portion of the second cup 130. For example, a height of an upper end of the collection wall part 161 of the first cup 160 may be greater than a height of an upper end of the collection wall part 131 of the second cup 130.

Chemical liquid falling along the collection wall part 161 is collected in the trench part 170. The trench part 170 may have an annular planar shape centered on the axis AX, similar to the trench part 140 of the second cup 130. However, in another embodiment of the present invention, the trench part of the first cup may surround the substrate support part and may extend along a closed-loop path that is not circular.

The drain port 180 is provided at one side of the trench part 170. The chemical liquid discharged from the table 115 and collected in the trench part 170 is discharged to the outside of the first cup 160 through the drain port 180. The chemical liquid discharged through the drain port 180 may move to the drain flow path 190 through a drain tube 182.

Similar to the bottom of the trench part 140 of the second cup 130, a bottom of the trench part 170 of the first cup 160 may include a first bottom part 174 and a second bottom part 177. The second bottom part 177 is stepped from the first bottom part 174 and is recessed further downward than the first bottom part 174.

A vertical cross-sectional shape of the second bottom part 177 may be a curved shape that is concavely recessed. A vertical cross-sectional shape of the first bottom part 174 may be an inclined linear shape in which a height increases in a width direction of the trench part 170 away from the second bottom part 177.

In the width direction of the trench part 170, a pair of first bottom parts 174 may be provided with the second bottom part 177 interposed therebetween. Shapes of the first bottom part 174, the second bottom part 177, and the drain port 180 of the trench part 170 of the first cup 160 are the same as shapes of the first bottom part 144, the second bottom part 147, and the drain port 150 of the trench part 140 of the second cup 130 described above, and thus redundant descriptions thereof will be omitted.

Since a height of the bottom of the trench part 170 decreases as the bottom becomes closer to the drain port 180 in a vertical direction of the bottom of the trench part 170, the chemical liquid collected in the trench part 170 may move toward the drain port 180 more quickly and may be discharged more quickly to the outside of the first cup 160 through the drain port 180.

The lifting actuator 270 may lift and lower the first cup 160 and the second cup 130. The second cup 130 and the first cup 160 may be coupled to each other, such that the lifting actuator 270 may simultaneously lift and lower the first cup 160 and the second cup 130.

For example, when the first chemical liquid is discharged from the first chemical liquid nozzle 122 and discharged to the outer peripheral portion of the table 115, the height position of the upper end of the collection wall part 161 of the first cup 160 may be higher than a height position of the substrate 10, and the height position of the upper end of the collection wall part 131 of the second cup 130 may be lower than the height position of the substrate 10.

Further, when the second chemical liquid is discharged from the second chemical liquid nozzle 125 and the third chemical liquid nozzle 127 and the second chemical liquid, or the mixed chemical liquid of the first chemical liquid and the second chemical liquid is discharged to the outer peripheral portion of the table 115, the height position of the upper end of the collection wall part 161 of the first cup 160 may be higher than the height position of the substrate 10, and the height position of the upper end of the collection wall part 131 of the second cup 130 may be lower than the height position of the substrate 10.

In this case, the level of the upper portion of the first cup 160 corresponds to a level of the substrate support part 110, and hereinafter, a position of the first cup 160 in this state will be referred to as a first cup position.

When the second chemical liquid is discharged from the second chemical liquid nozzle 125 and the third chemical liquid nozzle 127 and discharged to the outer peripheral portion of the table 115, the lifting actuator 270 may lift the second cup 130 and the first cup 160 such that the height of the upper end of the collection wall part 131 of the second cup 130, which is lower than the height of the upper end of the collection wall part 161 of the first cup 160, becomes higher than the height of the substrate 10.

In this case, the level of the upper portion of the second cup 130, which is different from the level of the upper portion of the first cup 160, corresponds to the level of the substrate support part 110, and hereinafter, a position of the second cup 130 in this state will be referred to as a second cup position.

When discharge of the second chemical liquid is stopped and the first chemical liquid is discharged again from the first chemical liquid nozzle 122 and discharged to the outer peripheral portion of the table 115, the lifting actuator 270 may lower the second cup 130 and the first cup 160 to original heights such that the height position of the upper end of the collection wall part 161 of the first cup 160 is higher than the height position of the substrate 10, and the height position of the upper end of the collection wall part 131 of the second cup 130 is lower than the height position of the substrate 10. That is, the first cup 160 may return to the first cup position.

The substrate processing apparatus 100A may further include the drain flow path 190 configured to guide the chemical liquid discharged from the second cup 130 through the drain port 150 to the outside of the substrate processing apparatus 100A.

The drain flow path 190 may be connected to the drain tube 152 of the second cup 130 and the drain tube 182 of the first cup 160. Accordingly, when the first chemical liquid or the second chemical liquid is discharged to the outside of the first cup 160, the first chemical liquid or the second chemical liquid may be drained to the outside of the substrate processing apparatus 100A through the drain flow path 190.

The chemical liquid recovery part 200A recovers the second chemical liquid discharged from the second cup 130 through the drain port 150. The chemical liquid recovery part 200A may include a recycling chemical liquid tank 201, a chemical liquid recovery flow path 204, and a flow path switching part 207.

The recycling chemical liquid tank 201 may accommodate the second chemical liquid discharged from the second cup 130. The chemical liquid recovery flow path 204 may branch from the drain flow path 190 and guide a chemical liquid flowing along the drain flow path 190 to the recycling chemical liquid tank 201.

The flow path switching part 207 selectively switches a flow direction of the second chemical liquid such that the second chemical liquid discharged from the second cup 130 and entering the drain flow path 190 is directed toward one of the outside of the substrate processing apparatus 100A and the recycling chemical liquid tank 201. The flow path switching part 207 may include, for example, a three-way valve.

The substrate processing apparatus 100A may further include a recycling chemical liquid supply part 220 and a control part 260.

The recycling chemical liquid supply part 220 may supply, to the discharge part 120, the second chemical liquid accommodated in the recycling chemical liquid tank 201, that is, a recycling chemical liquid. The recycling chemical liquid supply part 220 may include a recycling chemical liquid supply flow path 221, a pump 224, and a valve 226.

The recycling chemical liquid supply flow path 221 may guide the recycling chemical liquid to move from the recycling chemical liquid tank 201 to the discharge part 120. The recycling chemical liquid supply flow path 221 may include, for example, a pipe. The pump 224 may pump the recycling chemical liquid discharged from the recycling chemical liquid tank 201 toward the discharge part 120. The valve 226 opens and closes the recycling chemical liquid supply flow path 221 such that the recycling chemical liquid accommodated in the recycling chemical liquid tank 201 is selectively supplied to the discharge part 120.

Although not illustrated in FIG. 1, the recycling chemical liquid supply part 220 may further include a filter. The filter may filter impurities from the recycling chemical liquid supplied from the recycling chemical liquid tank 201 to the discharge part 120.

The control part 260 may control operations of the first chemical liquid supply part 240, the second chemical liquid supply part 230, the substrate support part 110, the discharge part 120, the first cup 160, the second cup 130, the lifting actuator 270, the chemical liquid recovery part 200A, and the recycling chemical liquid supply part 220, according to a sequence of operations performed through the substrate processing apparatus 100A.

For example, the control part 260 may control on/off operations of the pumps 224, 236, and 246 included in the substrate processing apparatus 100A, opening and closing of the valves 226, 238, and 248, opening and closing of the nozzles 122, 125, and 127, on/off operations of the spindle 112, upward driving and downward driving of the lifting actuator 270, and the operation of the flow path switching part 207.

For example, in a state in which the first cup 160 is in the first cup position, when the first chemical liquid is discharged from the first chemical liquid nozzle 122 of the discharge part 120, the control part 260 may control the flow path switching part 207 such that the first chemical liquid collected in the first cup 160 is drained toward the outside of the substrate processing apparatus 100A through the drain flow path 190. Further, when discharge of the first chemical liquid through the first chemical liquid nozzle 122 of the discharge part 120 is stopped and the second chemical liquid is discharged through the second chemical liquid nozzle 125 and the third chemical liquid nozzle 127, the control part 260 may control the flow path switching part 207 such that the second chemical liquid collected in the first cup 160 is drained toward the outside of the substrate processing apparatus 100A through the drain flow path 190.

In addition, in a state in which the second cup 130 is in the second cup position, when the second chemical liquid is discharged onto the substrate 10 from the second chemical liquid nozzle 125 and the third chemical liquid nozzle 127, the control part 260 may control the flow path switching part 207 such that, until the concentration of the second chemical liquid collected in the second cup 130 has become equal to the concentration of the second chemical liquid discharged onto the substrate 10, the second chemical liquid collected in the second cup 130 is directed to the outside of the substrate processing apparatus 100A.

After the concentration of the second chemical liquid collected in the second cup 130 has become equal to the concentration of the second chemical liquid discharged onto the substrate 10, the flow path switching part 207 may be controlled by the control part 260 such that the second chemical liquid collected in the second cup 130 is directed toward the recycling chemical liquid tank 201 of the chemical liquid recovery part 200A. Here, the concentration of the second chemical liquid discharged onto the substrate 10 may be equal to a concentration of the second chemical liquid accommodated in the second chemical liquid tank 231 of the second chemical liquid supply part 230.

For example, the first chemical liquid supplied to the discharge part 120 through the first chemical liquid supply part 240 may be DIW, and the second chemical liquid supplied to the discharge part 120 through the second chemical liquid supply part 230 may be HF.

In the state in which the first cup 160 is in the first cup position, the first chemical liquid is discharged onto the substrate 10 through the first chemical liquid nozzle 122, and then, the second chemical liquid is discharged onto the substrate 10 through the second chemical liquid nozzle 125 and the third chemical liquid nozzle 127.

The first cup 160 and the second cup 130 may be lifted by the lifting actuator 270 from a height shown in FIG. 2 to a height shown in FIG. 3 while the second chemical liquid is being discharged onto the substrate 10. In other words, the second cup 130 may move to the second cup position.

The second chemical liquid collected in the second cup 130 during a process of processing a previous substrate 10 may remain in the second cup 130 without being drained through the drain port 150. The second chemical liquid remaining in the second cup 130 may be concentrated over time for reasons such as evaporation of a solvent, and thus a concentration thereof may become higher. Alternatively, the second chemical liquid remaining in the second cup 130 may have a lower concentration.

In the state in which the second cup 130 is in the second cup position, when the second chemical liquid is discharged onto the substrate 10 through the second chemical liquid nozzle 125 and the third chemical liquid nozzle 127, in the trench part 140 of the second cup 130, the second chemical liquid remaining in the second cup 130 and having a different concentration, as described above, may be mixed with the second chemical liquid discharged onto the substrate 10 and discharged from the substrate support part 110.

Accordingly, at an initial time point at which collection of the second chemical liquid into the second cup 130 starts, the concentration of the second chemical liquid collected in the second cup 130 may be different from the concentration of the second chemical liquid discharged onto the substrate 10. For example, at the initial time point at which collection of the second chemical liquid into the second cup 130 starts, the concentration of the second chemical liquid collected in the second cup 130 may be higher than the concentration of the second chemical liquid discharged onto the substrate 10. The concentration of the second chemical liquid discharged onto the substrate 10 may be equal to the concentration of the second chemical liquid accommodated in the second chemical liquid tank 231.

However, when the second chemical liquid is continuously collected in the second cup 130 and continuously discharged through the drain port 150 in the state in which the second cup 130 is in the second cup position, the concentration of the second chemical liquid collected in the second cup 130 may be equal to the concentration of the second chemical liquid discharged onto the substrate 10. In other words, the concentration of the second chemical liquid collected in the second cup 130 may be adjusted to a concentration at which recycling is possible.

After a concentration of the second chemical liquid collected in the second cup 130 and staying in the trench part 140 has become equal to the concentration of the second chemical liquid accommodated in the second chemical liquid tank 231, the flow path switching part 207 may switch the second chemical liquid in the drain flow path 190 to be directed toward the recycling chemical liquid tank 201, so that the second chemical liquid may be supplied to the recycling chemical liquid tank 201.

As described above, since the trench part 140 includes the second bottom part 147 at the bottom thereof so that the second chemical liquid is quickly discharged from the trench part 140 to the outside of the second cup 130, a time required from a time point at which the second chemical liquid starts to be discharged onto the substrate 10 and starts to be collected in the second cup 130 until the concentration of the second chemical liquid collected in the second cup 130 has become equal to the concentration of the second chemical liquid accommodated in the second chemical liquid tank 231 may be reduced.

For example, in a case of the second cup not including the second bottom part 147, a time required from the time point at which the second chemical liquid starts to be discharged onto the substrate 10 and starts to be collected in the second cup until the concentration of the second chemical liquid collected in the second cup has become equal to the concentration of the second chemical liquid accommodated in the second chemical liquid tank 231 may be greater than a time required, in the case of the second cup 130 according to the first embodiment of the present invention, from an initial time point at which the second chemical liquid starts to be discharged onto the substrate 10 and starts to be collected in the second cup 130 until the concentration of the second chemical liquid collected in the second cup 130 has become equal to a concentration of the chemical liquid of the second chemical liquid supply part 230.

In other words, in the case of one embodiment of the present invention, the second chemical liquid during a preset time from a time point at which the second chemical liquid starts to be collected in the second cup 130 is drained to the outside through the drain flow path 190, but after the preset time elapses from the time point at which the second chemical liquid starts to be collected in the second cup 130, the control part 260 may control the flow path switching part 207 such that the second chemical liquid is recovered to and recycling in the recycling chemical liquid tank 201. Accordingly, a recycling rate of the chemical liquid may be increased.

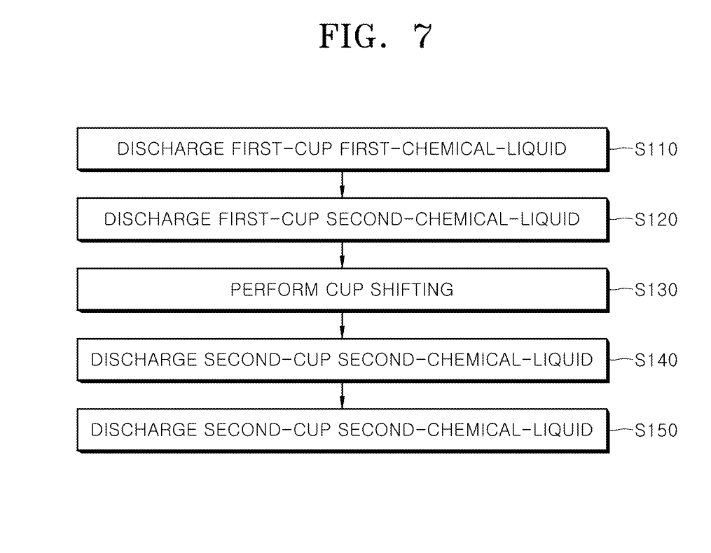

FIG. 7 is a block diagram illustrating an example of a substrate processing method according to one embodiment of the present invention. The substrate processing method illustrated in FIG. 7 may be an example of a substrate processing method using the substrate processing apparatus 100A according to the first embodiment of the present invention.

Referring to FIGS. 1 to 7, the substrate processing method according to one embodiment of the present invention may be a method of cleaning the substrate 10 using the substrate processing apparatus 100A according to the first embodiment of the present invention.

The substrate processing method includes a first-cup first-chemical-liquid discharge operation S110, a first-cup second-chemical-liquid discharge operation S120, a cup shifting operation S130, a second-cup second-chemical-liquid discharge operation S140, and a second chemical liquid recovery operation S150.

The first-cup first-chemical-liquid discharge operation S110 is an operation of discharging a first chemical liquid at a first cup position, at which a level of an upper portion of the first cup 160 corresponds to a level of the substrate support part 110, onto the substrate 10 supported by the substrate support part 110.

The first chemical liquid that is positioned at the first cup position, discharged onto the substrate 10, discharged from the substrate support part 110, and collected in the first cup 160 is drained from the first cup 160 through the drain port 180 and discharged to the outside of the substrate processing apparatus 100A through the drain flow path 190.

Since the first cup position has already been described in the description of the substrate processing apparatus 100A according to the present invention, a redundant description thereof will be omitted. As illustrated in FIG. 2, at the first cup position, an upper end of the first cup 160 may be slightly higher than a height position of the substrate 10 supported by the substrate support part 110, and an upper end of the second cup 130 may be slightly lower than the height position of the substrate 10.

The first-cup second-chemical-liquid discharge operation is an operation of stopping the discharge of the first chemical liquid and discharging, onto the substrate 10, a second chemical liquid different from the first chemical liquid while maintaining the first cup position. The second chemical liquid that is positioned at the first cup position, discharged onto the substrate 10, discharged from the substrate support part 110, and collected in the first cup 160 is drained from the first cup 160 through the drain port 180 and discharged to the outside of the substrate processing apparatus 100A through the drain flow path 190.

The cup shifting operation S130 is an operation of moving the second cup 130 to a second cup position at which a level of an upper portion of the second cup 130 corresponds to the level of the substrate support part 110. The cup shifting operation S130 may be performed by an operation of the lifting actuator 270.

Since the second cup position has already been described in the description of the substrate processing apparatus 100A according to the present invention, a redundant description thereof will be omitted. As illustrated in FIG. 3, at the second cup position, the upper end of the second cup 130 may be slightly higher than the height position of the substrate 10 supported by the substrate support part 110, and the upper end of the first cup 160 may be higher than the upper end of the second cup 130.

The second-cup second-chemical-liquid discharge operation S140 is an operation of discharging the second chemical liquid at the second cup position onto the substrate 10. When the cup shifting operation S130 is performed while the second chemical liquid is being discharged onto the substrate 10, the second-cup second-chemical-liquid discharge operation S140 may be performed simultaneously with the second cup 130 being moved to the second cup position.

The second chemical liquid discharged onto the substrate 10 and discharged from the substrate support part 110 in the second-cup second-chemical-liquid discharge operation S140 is collected in the second cup 130. As described in the description of the substrate processing apparatus 100A, at an initial time point of the second-cup second-chemical-liquid discharge operation S140, the second chemical liquid collected in the second cup 130 may include the second chemical liquid remaining in the second cup 130 from a previous substrate processing process.

Accordingly, at the initial time point of the second-cup second-chemical-liquid discharge operation, a concentration of the second chemical liquid collected in the second cup 130 may be different from a concentration of the second chemical liquid discharged onto the substrate 10, that is, a concentration of the second chemical liquid accommodated in the second chemical liquid tank 231. For example, at the initial time point of the second-cup second-chemical-liquid discharge operation, the concentration of the second chemical liquid collected in the second cup 130 may be higher than the concentration of the second chemical liquid discharged onto the substrate 10, that is, the concentration of the second chemical liquid accommodated in the second chemical liquid tank 231.

Meanwhile, in another embodiment of the present invention, at the initial time point of the second-cup second-chemical-liquid discharge operation, the concentration of the second chemical liquid collected in the second cup 130 may be lower than the concentration of the second chemical liquid discharged onto the substrate 10, that is, the concentration of the second chemical liquid accommodated in the second chemical liquid tank 231.

The second chemical liquid recovery operation S150 is an operation of recovering the second chemical liquid after a concentration of the second chemical liquid that is positioned at the second cup position, discharged onto the substrate 10, discharged from the substrate support part 110, and collected in the second cup 130 has become equal to a concentration of the second chemical liquid discharged to the second cup 130, that is, the concentration of the second chemical liquid accommodated in the second chemical liquid tank 231.

The second chemical liquid recovery operation S150 may be performed by the chemical liquid recovery part 200A. The recovered second chemical liquid may be accommodated in the recycling chemical liquid tank 201.

The second chemical liquid recovery operation S150 may be initiated after a preset time has elapsed since the initial time point of the second-cup second-chemical-liquid discharge operation S140. A time elapsed from the initial time point of the second-cup second-chemical-liquid discharge operation S140 until a concentration of the chemical liquid collected in the second cup 130 has become equal to the concentration of the second chemical liquid accommodated in the second chemical liquid tank 231 may be identified in advance through repeated tests, and the identified time may be set as the preset time described above.

The second chemical liquid collected in the second cup 130 between the initial time point of the second-cup second-chemical-liquid discharge operation S140 and an initial time point of the second chemical liquid recovery operation S150 may be discharged from the second cup 130 through the drain port 150 and drained to the outside of the substrate processing apparatus 100A through the drain flow path 190.

The second chemical liquid recovered in the recycling chemical liquid tank 201 may be discharged onto the substrate 10 for processing the substrate 10 supported by the substrate support part 110. Alternatively, the recovered second chemical liquid may be discharged onto a subsequent substrate 10 or may be used later for processing the substrate 10.

Although not illustrated in FIG. 7, the substrate processing method according to one embodiment of the present invention may further include loading the substrate 10 onto the substrate support part 110 before the first-cup first-chemical-liquid discharge operation S110.

In addition, the substrate processing method according to one embodiment of the present invention may further include, after impurities are removed from the substrate 10 through the second-cup second-chemical-liquid discharge operation S140, returning the first cup 160 to the first cup position, i.e., lowering the first cup 160 and the second cup 130 to their original positions as shown in FIG. 2, discharging the first chemical liquid onto the substrate 10 to rinse the substrate 10, drying the substrate 10, and unloading the substrate 10 from the substrate support part 110.

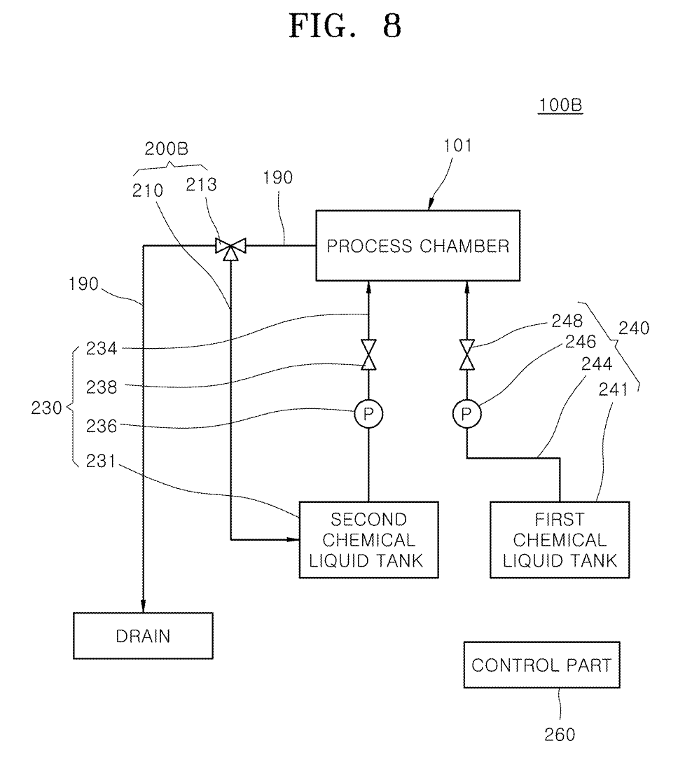

FIG. 8 is a configuration diagram of a substrate processing apparatus according to a second embodiment of the present invention. Referring to FIGS. 2 and 8, a substrate processing apparatus 100B according to the second embodiment of the present invention may include a process chamber 101, a second chemical liquid supply part 230, a first chemical liquid supply part 240, a chemical liquid recovery part 200B, a drain flow path 190, and a control part 260.

The process chamber 101 may include therein the substrate support part 110, the discharge part 120, the first cup 160, the second cup 130, the drain tubes 152 and 182, and the lifting actuator 270 illustrated in FIGS. 2 and 3. Since the substrate support part 110, the discharge part 120, the first cup 160, the second cup 130, the drain tubes 152 and 182, and the lifting actuator 270 have already been described in connection with the substrate processing apparatus 100A according to the first embodiment of the present invention, redundant descriptions thereof will be omitted.

The first chemical liquid supply part 240, the second chemical liquid supply part 230, the drain flow path 190, and the control part 260 have also already been described in connection with the substrate processing apparatus 100A according to the first embodiment of the present invention, and thus redundant descriptions thereof will be omitted.

The chemical liquid recovery part 200B may include a chemical liquid recovery flow path 210 and a flow path switching part 213. The chemical liquid recovery flow path 210 branches from the drain flow path 190 and guides a second chemical liquid flowing along the drain flow path 190 to the second chemical liquid tank 231.

The flow path switching part 213 may selectively switch a flow direction of the second chemical liquid such that the second chemical liquid discharged from the second cup 130 and entering the drain flow path 190 is directed toward one of the outside of the substrate processing apparatus 100B and the second chemical liquid tank 231. The flow path switching part 213 may include, for example, a three-way valve.

Before a concentration of the second chemical liquid collected in the second cup 130 has become equal to a concentration of the second chemical liquid in the second chemical liquid tank 231, the flow path switching part 213 is controlled such that the second chemical liquid collected in the second cup 130 is directed toward the outside of the substrate processing apparatus 100B.

Meanwhile, after the concentration of the second chemical liquid collected in the second cup 130 has become equal to the concentration of the second chemical liquid in the second chemical liquid tank 231, the flow path switching part 213 is controlled such that the second chemical liquid collected in the second cup 130 is directed toward the second chemical liquid tank 231. The recycling second chemical liquid introduced into the second chemical liquid tank 231 may be combined with the existing second chemical liquid in the second chemical liquid tank 231 and may be discharged onto the substrate 10 through the discharge part 120.

According to the substrate processing apparatuses 100A and 100B and the substrate processing method described above, a chemical liquid used in substrate processing may be reused to reduce a consumption amount of the chemical liquid used in the substrate processing, thereby reducing operating costs.

In addition, an amount of waste chemical liquid discharged due to substrate processing is reduced, thereby reducing a burden of environmental pollution, and purification treatment costs of the waste chemical liquid may also be reduced.

According to the present invention, since a chemical liquid used in substrate processing is recycled, consumption of the chemical liquid used in the substrate processing can be reduced, and operating costs can be reduced.

According to the present invention, since the amount of waste chemical liquid discharged during substrate processing can be reduced, the burden of environmental pollution can be reduced, and purification treatment costs for the waste chemical liquid can also be reduced.

The present invention has been described with reference to embodiments illustrated in the accompanying drawings. However, this is merely exemplary, and those of ordinary skill in the art will understand that various modifications and other equivalent embodiments may be made therefrom. Accordingly, the true scope of protection of the present invention should be determined only by the appended claims.

What is claimed is:

1. A substrate processing apparatus comprising:
a substrate support part configured to support a substrate;
a discharge part configured to discharge a chemical liquid onto the substrate; and
a cup including a collection wall part surrounding the substrate support part such that the chemical liquid discharged from the substrate support part after being discharged onto the substrate is collected, a trench part in which the chemical liquid falling along the collection wall part is collected, and a drain port provided at one side of the trench part such that the chemical liquid is discharged from the trench part,
wherein a bottom of the trench part includes a first bottom part and a second bottom part stepped from the first bottom part and recessed further downward than the first bottom part.

2. The substrate processing apparatus of claim 1, wherein a vertical cross-sectional shape of the second bottom part is a curved shape that is concavely recessed.

3. The substrate processing apparatus of claim 1, wherein a vertical cross-sectional shape of the first bottom part is an inclined linear shape in which a height increases in a width direction of the trench part away from the second bottom part.

4. The substrate processing apparatus of claim 1, wherein the first bottom part is provided as a pair of first bottom parts with the second bottom part interposed therebetween in a width direction of the trench part.

5. The substrate processing apparatus of claim 1, wherein, in a width direction of the trench part, a width occupied by the second bottom part is greater than a width occupied by the first bottom part.

6. The substrate processing apparatus of claim 1, wherein the trench part extends along a closed-loop path surrounding the substrate support part, and
a height of the bottom of the trench part is lowest at a point at which the drain port is located and increases away from the point at which the drain port is located.

7. The substrate processing apparatus of claim 1, wherein the chemical liquid includes a first chemical liquid and a second chemical liquid different from the first chemical liquid, and
the cup includes a first cup that collects at least one of the first chemical liquid and the second chemical liquid, and a second cup configured to collect the second chemical liquid while being configured not to collect the first chemical liquid.

8. A substrate processing apparatus comprising:
a substrate support part configured to support a substrate;
a discharge part configured to discharge a chemical liquid onto the substrate; and
a cup including a collection wall part surrounding the substrate support part such that the chemical liquid discharged from the substrate support part after being discharged onto the substrate is collected, a trench part extending along a closed-loop path surrounding the substrate support part and configured to collect the chemical liquid falling along the collection wall part, and a drain port provided at one side of the trench part such that the chemical liquid is discharged from the trench part,
wherein a height of a bottom of the trench part is lowest at a point at which the drain port is located and increases away from the point at which the drain port is located.

9. The substrate processing apparatus of claim 8, wherein the chemical liquid includes a first chemical liquid and a second chemical liquid different from the first chemical liquid, and
the cup includes a first cup that collects at least one of the first chemical liquid and the second chemical liquid, and a second cup configured to collect the second chemical liquid while being configured not to collect the first chemical liquid.

10. The substrate processing apparatus of claim 9, further comprising:
a drain flow path configured to guide the second chemical liquid discharged from the second cup to an outside of the substrate processing apparatus; and
a chemical liquid recovery part configured to recover the second chemical liquid discharged from the second cup.

11. The substrate processing apparatus of claim 10, wherein the chemical liquid recovery part includes:
a recycling chemical liquid tank in which the second chemical liquid discharged from the second cup is accommodated;
a chemical liquid recovery flow path branched from the drain flow path and configured to guide the second chemical liquid flowing along the drain flow path to the recycling chemical liquid tank; and
a flow path switching part configured to selectively switch a flow direction of the second chemical liquid such that the second chemical liquid discharged from the second cup and entering the drain flow path is directed toward one of the recycling chemical liquid tank and the outside of the substrate processing apparatus.

12. The substrate processing apparatus of claim 11, wherein the flow path switching part is controlled to direct the second chemical liquid collected in the second cup toward the outside of the substrate processing apparatus before a concentration of the second chemical liquid collected in the second cup has become equal to a concentration of the second chemical liquid supplied to the discharge part, and to direct the second chemical liquid collected in the second cup toward the recycling chemical liquid tank after the concentration of the second chemical liquid collected in the second cup has become equal to the concentration of the second chemical liquid supplied to the discharge part.

13. The substrate processing apparatus of claim 10, further comprising:
a first chemical liquid tank configured to accommodate the first chemical liquid supplied to the discharge part; and
a second chemical liquid tank configured to accommodate the second chemical liquid supplied to the discharge part,
wherein the chemical liquid recovery part includes:
a chemical liquid recovery flow path branched from the drain flow path and configured to guide the chemical liquid flowing along the drain flow path to the second chemical liquid tank; and
a flow path switching part configured to selectively switch a flow direction of the second chemical liquid such that the second chemical liquid discharged from the second cup and entering the drain flow path is directed toward one of the second chemical liquid tank and the outside of the substrate processing apparatus.

14. The substrate processing apparatus of claim 13, wherein the flow path switching part is controlled to direct the second chemical liquid collected in the second cup toward the outside of the substrate processing apparatus before a concentration of the second chemical liquid collected in the second cup has become equal to a concentration of the second chemical liquid in the second chemical liquid tank, and to direct the second chemical liquid collected in the second cup toward the second chemical liquid tank after the concentration of the second chemical liquid collected in the second cup has become equal to the concentration of the second chemical liquid in the second chemical liquid tank.

15. A substrate processing method comprising:
a first-cup first-chemical-liquid discharge operation of discharging a first chemical liquid at a first cup position, at which a level of an upper portion of a first cup corresponds to a level of a substrate support part, onto a substrate supported by the substrate support part;
a first-cup second-chemical-liquid discharge operation of stopping the discharging of the first chemical liquid and discharging a second chemical liquid different from the first chemical liquid onto the substrate while maintaining the first cup position;
a cup shifting operation of moving a second cup to a second cup position at which a level of an upper portion of the second cup corresponds to the level of the substrate support part; and
a second-cup second-chemical-liquid discharge operation of discharging the second chemical liquid at the second cup position onto the substrate.

16. The substrate processing method of claim 15, further comprising a second chemical liquid recovery operation of recovering the second chemical liquid after a concentration of the second chemical liquid that is positioned at the second cup position, discharged onto the substrate, and collected in the second cup has become equal to a concentration of the second chemical liquid discharged to the second cup.

17. The substrate processing method of claim 16, wherein, at an initial time point of the second-cup second-chemical-liquid discharge operation, the concentration of the second chemical liquid collected in the second cup is different from the concentration of the second chemical liquid discharged to the second cup.

18. The substrate processing method of claim 16, wherein the second chemical liquid recovery operation is initiated after a preset time has elapsed from an initial time point of the second-cup second-chemical-liquid discharge operation.

19. The substrate processing method of claim 15, wherein the second cup includes a collection wall part surrounding the substrate support part such that the second chemical liquid discharged from the substrate support part after being discharged onto the substrate is collected, a trench part configured to collect the second chemical liquid falling along the collection wall part, and a drain port provided at one side of the trench part such that the second chemical liquid is discharged from the trench part, and
a bottom of the trench part includes a first bottom part and a second bottom part stepped from the first bottom part and recessed further downward than the first bottom part.

20. The substrate processing method of claim 15, wherein the second cup includes a collection wall part surrounding the substrate support part such that the second chemical liquid discharged from the substrate support part after being discharged onto the substrate is collected, a trench part extending along a closed-loop path surrounding the substrate support part and configured to collect the second chemical liquid falling along the collection wall part, and a drain port provided at one side of the trench part such that the second chemical liquid is discharged from the trench part, and
a height of a bottom of the trench part is lowest at a point at which the drain port is located and increases away from the point at which the drain port is located.
